(19) United States
(12) Patent Application Publication
(10) Pub. No.: US 2023/0238224 A1
(43) Pub. Date: Jul. 27, 2023

(54) MEMBER FOR SEMICONDUCTOR MANUFACTURING APPARATUS

(71) Applicant: NGK Insulators, Ltd., Nagoya-City (JP)

(72) Inventors: Seiya INOUE, Handa-City (JP); Tatsuya KUNO, Nagoya-City (JP); Shinya YOSHIDA, Nagoya-City (JP); Tomoki NAGAE, Nagoya-City (JP); Yusuke OGISO, Nagakute-City (JP); Takuya YOTO, Nagoya-City (JP)

(73) Assignee: NGK Insulators, Ltd., Nagoya-City (JP)

(21) Appl. No.: 18/056,802

(22) Filed: Nov. 18, 2022

(30) Foreign Application Priority Data
Jan. 21, 2022 (JP) 2022-007943

(51) Int. Cl. H01J 37/32; H01L 21/683

(52) U.S. Cl. CPC H01J 37/32715; H01J 37/3244; H01L 21/6833; H01J 2237/327

(57) ABSTRACT

A member for semiconductor manufacturing apparatus has a ceramic plate, a porous plug, an insulating lid, and pores. The ceramic plate has a wafer placement surface as an upper surface. The porous plug is disposed in a plug insertion hole penetrating the ceramic plate in an up-down direction, and allows a gas to flow. The insulating lid is provided in contact with an upper surface of the porous plug, and exposed to the wafer placement surface. A plurality of pores are provided in the insulating lid, and penetrate the insulating lid in an up-down direction.

### BACKGROUND OF THE INVENTION

### 1. Field of the Invention

The present invention relates to a member for semiconductor manufacturing apparatus.

### 2. Description of the Related Art

In a known member for semiconductor manufacturing apparatus in the related art, an electrostatic chuck having a wafer placement surface is provided on a cooling device. For example, the member for semiconductor manufacturing apparatus in PTL 1 includes: a gas supply hole provided in a cooling device; a recess section provided in an electrostatic chuck so as to communicate with the gas supply hole; pores penetrating from the bottom surface of the recess section to a wafer placement surface; and a porous plug composed of an insulating material filled in the recess section. When a back side gas such as helium is introduced into the gas supply hole, the gas is supplied to the space on the rear-surface side of the wafer through the gas supply hole, the porous plug and the pores.

### CITATION LIST

### Patent Literature

PTL 1: JP 2013-232640 A

### SUMMARY OF THE INVENTION

However, in the above-mentioned member for semiconductor manufacturing apparatus, the bottom of the recess section of the ceramic plate included in the electrostatic chuck is provided with pores, thus, it has been difficult in machining to reduce the length of the pores in an up-down direction.

The present invention has been devised to address such a problem, and it is a main object to improve machinability of pores that allow the wafer placement surface and the upper surface of the porous plug to communicate with each other.

The member for semiconductor manufacturing apparatus of the present invention includes: a ceramic plate having a wafer placement surface as an upper surface; a porous plug that is disposed in a plug insertion hole penetrating the ceramic plate in an up-down direction, and allows a gas to flow; an insulating lid that is provided in contact with an upper surface of the porous plug, and exposed to the wafer placement surface; and a plurality of pores penetrating the insulating lid in an up-down direction.

In the member for semiconductor manufacturing apparatus, the insulating lid which is a separate body from the ceramic plate is provided with a plurality of pores. Thus, the machinability of the pores is improved, as compared to when the ceramic plate is directly provided with a plurality of pores.

In the member for semiconductor manufacturing apparatus of the present invention, the insulating lid may be a thermal spray film or a ceramic bulk body. Under this condition, the insulating lid can be manufactured relatively easily.

In the member for semiconductor manufacturing apparatus of the present invention, the wafer placement surface may have a large number of small projections that support a wafer, an upper surface of the insulating lid may be at the same height as a reference surface of the wafer placement surface, the reference surface being not provided with the small projections, and the pores may have a length of 0.01 mm or more and 0.5 mm or less in an up-down direction. In this manner, the height of the space between the rear surface of the wafer and the upper surface of the porous plug is maintained at a low level, thus it is possible to prevent arc discharge from occurring in the space. In this case, the insulating lid may be a ceramic bulk body, and may have a rear surface bonded to the ceramic plate via an adhesive layer. In this manner, deterioration of the adhesive layer is also prevented. This is because an arc discharge in the space between the rear surface of the wafer and the upper surface of the porous plug is prevented. Note that the height of a reference surface may vary by small projection. The height of a reference surface may be the same as the height of the bottom surface of a small projection closest to the plug insertion hole.

In the member for semiconductor manufacturing apparatus of the present invention, the pores may have a diameter of 0.01 mm or more and 0.5 mm or less, and the insulating lid may be provided with the pores that are five or more in number. In this setting, the gas supplied to the porous plug smoothly flows to the rear surface of the wafer.

In the member for semiconductor manufacturing apparatus of the present invention, the plug insertion hole may have a female thread portion on an inner peripheral surface, and the porous plug may have a male thread portion to be screwed into the female thread portion, on an outer peripheral surface. In this manner, the porous plug can be disposed in the plug insertion hole without using a bonding adhesive. In an area where the male thread portion is screwed into the female thread portion, a vertical gap is unlikely to occur and a creepage distance is increased, thus, electrical discharge can be sufficiently prevented in the area.

In the member for semiconductor manufacturing apparatus of the present invention, the porous plug may have an enlarged-diameter section that has a larger diameter at a lower position. In this manner, the porous plug can be prevented from floating due to the pressure of a gas supplied from the lower surface of the porous plug.

In the member for semiconductor manufacturing apparatus of the present invention, the outer shape of the insulating lid and the porous plug may be a circle, and the outer diameter of the insulating lid may be larger than the outer diameter of the porous plug. In this manner, the adhesion area between the insulating lid and the ceramic plate is increased, thus the adhesiveness between the two becomes favorable.

The member for semiconductor manufacturing apparatus of the present invention may include: a conductive substrate provided in the lower surface of the ceramic plate; and a communication hole provided in the conductive substrate to communicate with the porous plug. The lower surface of the porous plug may be located inside the communication hole. In this manner, it is possible to prevent arc discharge from occurring between the lower surface of the porous plug and the conductive substrate.

### BRIEF DESCRIPTION OF THE DRAWINGS

FIG. 1 is a vertical cross-sectional view of a member 10 for semiconductor manufacturing apparatus.

FIG. 2 is a plan view of a ceramic plate 20.

FIG. 3 is a partially enlarged view of FIG. 1.

FIGS. 4A to 4C are manufacturing process diagrams of the member 10 for semiconductor manufacturing apparatus.

FIGS. 5A to 5D are manufacturing process diagrams of the member 10 for semiconductor manufacturing apparatus.

FIG. 6 is a partially enlarged view of a structure including an insulating lid 156.

FIG. 7 is a partially enlarged view illustrating another example of a porous plug 50.

FIG. 8 is a vertical cross-sectional view of an insulating plug 160.

FIGS. 9A to 9F are vertical cross-sectional views of porous plugs 150 to 650.

FIGS. 10A to 10C are vertical cross-sectional views of other examples of an insulating lid 56.

### DETAILED DESCRIPTION OF THE INVENTION

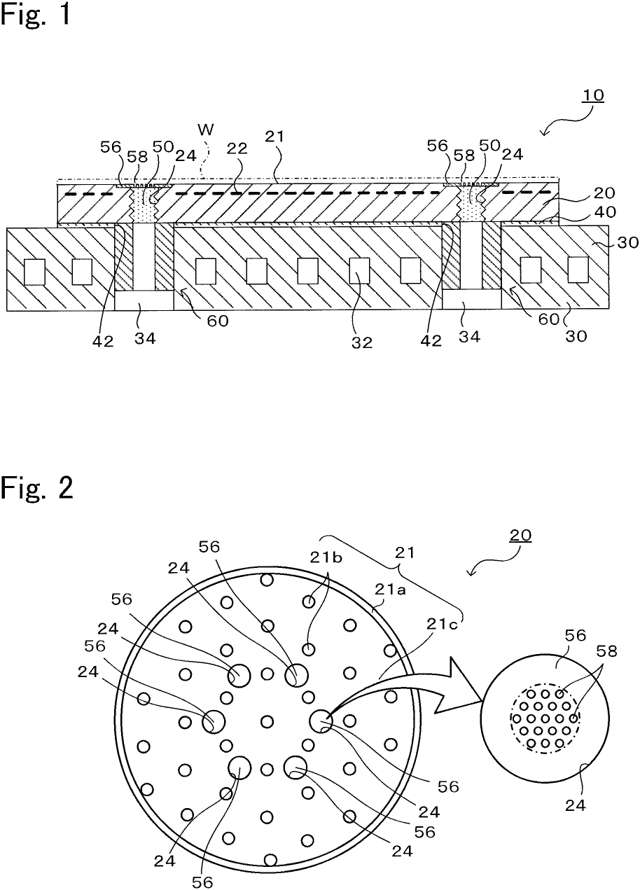

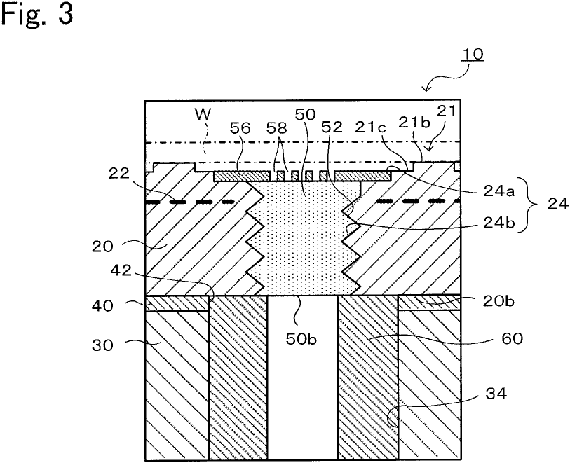

Next, a preferred embodiment of the present invention will be described with reference to the drawings. FIG. 1 is a vertical cross-sectional view of a member 10 for semiconductor manufacturing apparatus, FIG. 2 is a plan view of a ceramic plate 20, and FIG. 3 is a partially enlarged view of FIG. 1.

The member 10 for semiconductor manufacturing apparatus includes a ceramic plate 20, a cooling plate 30, a metal joining layer 40, a porous plug 50, an insulating lid 56, and an insulating pipe 60.

The ceramic plate 20 is a ceramic circular plate (for example, a diameter of 300 mm, a thickness of 5 mm) such as an alumina sintered body and an aluminum nitride sintered body. The upper surface of the ceramic plate 20 is a wafer placement surface 21. An electrode 22 is embedded in the ceramic plate 20. As illustrated in FIG. 2, on the wafer placement surface 21 of the ceramic plate 20, a seal band 21a is formed along the outer edge, and a plurality of small circular projections 21b are formed on the entire surface. The seal band 21a and the small circular projections 21b have the same height, which is several µm to several tens µm. The electrode 22 is a planar mesh electrode that is used as an electrostatic electrode, and a DC voltage can be applied thereto. When a DC voltage is applied to the electrode 22, a wafer W is absorbed and fixed to the wafer placement surface 21 (specifically, the upper surface of the seal band 21a and the upper surfaces of the small circular projections 21b) by an electrostatic adsorption force, and when application of the DC voltage is released, the adsorption and fixation of the wafer W to the wafer placement surface 21 is released. Note that the area of the wafer placement surface 21, which is not provided with the seal band 21a and the small circular projections 21b, is referred to as a reference surface 21c.

The plug insertion hole 24 is a through-hole that penetrates the ceramic plate 20 in an up-down direction. As illustrated in FIG. 3, the upper portion of the plug insertion hole 24 is a flat cylindrical member 24a without a female thread portion, and the lower portion is a female thread portion 24b. Multiple sections (for example, multiple sections provided at regular intervals in a circumferential direction as illustrated in FIG. 2) of the ceramic plate 20 are each provided with the plug insertion hole 24. The later-described porous plug 50 is disposed in the plug insertion hole 24.

The cooling plate 30 is a circular plate (circular plate with a diameter equal to or larger than the diameter of the ceramic plate 20) having a favorable thermal conductivity. A refrigerant flow path 32 through which a refrigerant circulates and a gas hole 34 for supplying a gas to the porous plug 50 are formed inside the cooling plate 30. The refrigerant flow path 32 is formed in the entirety of the cooling plate 30 in a plan view from an entrance to an exit in a one-stroke pattern. The gas hole 34 is a hole in a cylindrical shape, and is provided at a position opposed to the plug insertion hole 24. The material for the cooling plate 30 includes, for example, a metal material and a metal matrix composite (MMC). The metal material includes Al, Ti, Mo or an alloy of these. The MMC includes a material containing Si, SiC and Ti (also referred to as SiSiCTi) and a material obtained by impregnating a SiC porous body with Al and/or Si. As the material for the cooling plate 30, it is preferable to select a material with a thermal expansion coefficient closer to that of the material for the ceramic plate 20. The cooling plate 30 is also used as an RF electrode. Specifically, an upper electrode (not illustrated) is disposed above the wafer placement surface 21, and when high-frequency power is applied to parallel plate electrodes comprised of the upper electrode and the cooling plate 30, a plasma is generated.

The metal joining layer 40 joins the lower surface of the ceramic plate 20 to the upper surface of the cooling plate 30. The metal joining layer 40 is formed, for example, by thermal compression bonding (TCB). The TCB is a publicly known method in which a metal joining material is inserted between two members to be joined, and the two members are pressure-bonded with heated at a temperature lower than or equal to the solidus temperature of the metal joining material. The metal joining layer 40 has a circular hole 42 penetrating the metal joining layer 40 in an up-down direction at a position opposed to the gas hole 34. The metal joining layer 40 and the cooling plate 30 of this embodiment correspond to the conductive substrate of the present invention, and the circular hole 42 and the gas hole 34 correspond to the communication hole.

The porous plug 50 is a plug that allows a gas to flow, and is disposed in the plug insertion hole 24. The outer peripheral surface of the porous plug 50 conforms (is in contact with) the inner peripheral surface of the plug insertion hole 24. The porous plug 50 is in a cylindrical shape, and has a male thread portion 52 on an outer peripheral surface. The male thread portion 52 is screwed into the female thread portion 24b of the plug insertion hole 24. The upper surface of the porous plug 50 conforms the bottom surface of the cylindrical member 24a of the plug insertion hole 24. A lower surface 50b of the porous plug 50 conforms a lower surface 20b of the ceramic plate 20. In this embodiment, the porous plug 50 is a porous bulk body obtained through sintering using ceramic powder. As a ceramic, for example, alumina and aluminum nitride may be used. The porosity of the porous plug 50 is preferably 30% or more, and the average pore diameter is preferably 20 µm or more.

The insulating lid 56 is a circular plate member composed of ceramic (such as alumina). The insulating lid 56 is provided inside the cylindrical member 24a of the plug insertion hole 24 so as to be in contact with the upper surface of the porous plug 50, and is exposed to the wafer placement surface 21. The upper surface of the insulating lid 56 is at the same height as the reference surface 21c. The insulating lid 56 has a plurality of pores 58. The pores 58 are provided to penetrate the insulating lid 56 in an up-down direction. The length (the thickness of the insulating lid 56) of the pores 58 in an up-down direction is preferably, 0.01 mm or more and 0.5 mm or less, more preferably, 0.05 mm or more and 0.2 mm or less, and particularly preferably, 0.05 mm or more and 0.1 mm or less in a device in which a high voltage is applied. The diameter of the pores 58 is preferably, 0.01 mm or more and 0.5 mm or less, more preferably, 0.1 mm or more and 0.5 mm or less, and further preferably, 0.1 mm or more and 0.2 mm or less. The insulating lid 56 is preferably provided with the pores 58 that are five or more in number, and more preferably provided with the pores 58 that are 10 or more in number. The insulating lid 56 may be dense or porous, but is preferably dense.

The insulating pipe 60 is a circular pipe in a plan view, composed of dense ceramic (such as dense alumina). The outer peripheral surface of the insulating pipe 60 is bonded to the inner peripheral surface of the circular hole 42 of the metal joining layer 40 and the inner peripheral surface of the gas hole 34 of the cooling plate 30 via an adhesive layer which is not illustrated. The adhesive layer may be an organic adhesive layer (resin adhesive layer), or an inorganic adhesive layer. Note that the adhesive layer may be further provided between the upper surface of the insulating pipe 60 and the lower surface of the ceramic plate 20. The inside of the insulating pipe 60 communicates with the porous plug 50. Therefore, when a gas is introduced to the inside of the insulating pipe 60, the gas is supplied to the rear surface of the wafer W through the porous plug 50.

Next, an example of use of thus configured member 10 for semiconductor manufacturing apparatus will be described. First, a wafer W is placed on the wafer placement surface 21 with the member 10 for semiconductor manufacturing apparatus installed in a chamber which is not illustrated. The pressure in the chamber is then reduced and adjusted by a vacuum pump to achieve a predetermined degree of vacuum, and a DC voltage is applied to the electrode 22 of the ceramic plate 20 to generate an electrostatic adsorption force and cause the wafer W to be absorbed and fixed to the wafer placement surface 21 (specifically, the upper surface of the seal band 21a and the upper surfaces of the small circular projections 21b). Next, a reactive gas atmosphere with a predetermined pressure (for example, several 10s to several 100s of Pa) is formed in the chamber, and in this state, a high-frequency voltage is applied across an upper electrode (not illustrated) provided in a ceiling portion in the chamber and the cooling plate 30 of the member 10 for semiconductor manufacturing apparatus to generate a plasma. The surface of the wafer W is processed by the generated plasma. A refrigerant is circulated through the refrigerant flow path 32 of the cooling plate 30. A back side gas is introduced into the gas hole 34 from a gas cylinder which is not illustrated. A heat transfer gas (for example, helium) is used as the back side gas. The back side gas is supplied and enclosed in the space between the rear surface of the wafer W and the reference surface 21c of the wafer placement surface 21 through the insulating pipe 60, the porous plug 50 and the plurality of pores 58. Heat is efficiently transferred between the wafer W and the ceramic plate 20 due to the presence of the back side gas.

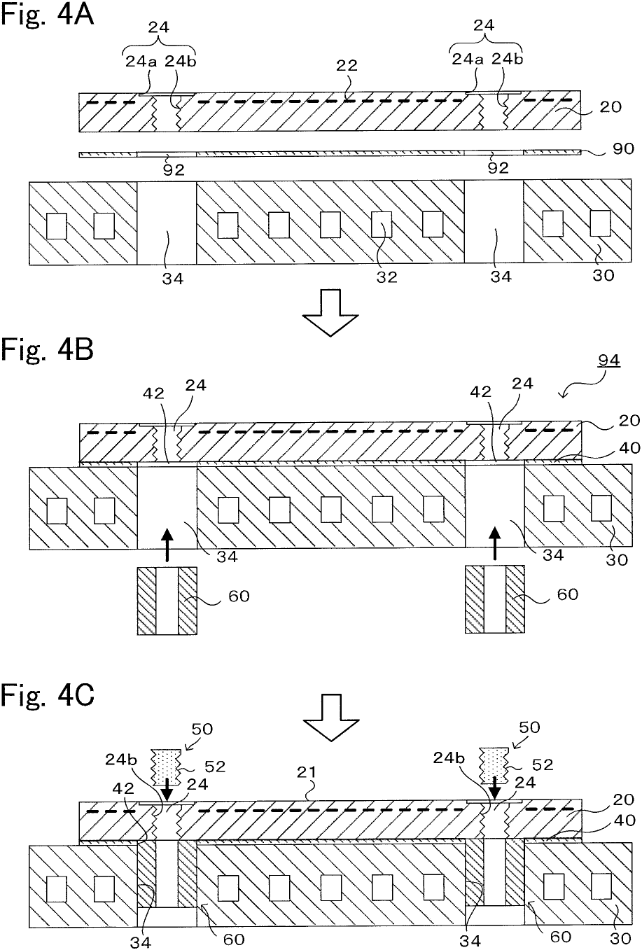

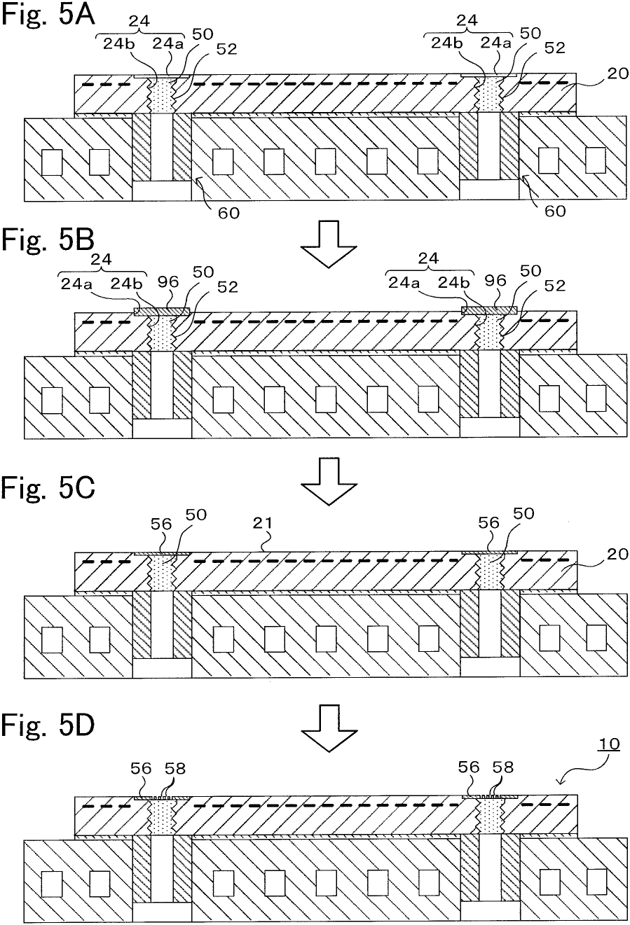

Next, a manufacturing example of the member 10 for semiconductor manufacturing apparatus will be described with reference to FIGS. 4A to 4C and FIGS. 5A to 5D. FIGS. 4A to 4C and FIGS. 5A to 5D are manufacturing process diagrams of the member 10 for semiconductor manufacturing apparatus. First, the ceramic plate 20, the cooling plate 30 and a metal joining material 90 are prepared (FIG. 4A). The ceramic plate 20 includes the electrode 22 and the plug insertion hole 24. In this stage, the upper surface of the ceramic plate 20 is a flat surface, and is not provided with any seal band 21a and any small circular projection 21b. The upper portion of the plug insertion hole 24 is the cylindrical member 24a without a female thread portion, and the lower portion is the female thread portion 24b. The cooling plate 30 has the embedded refrigerant flow path 32, and includes the gas hole 34. The metal joining material 90 includes a circular hole 92 which finally becomes the circular hole 42.

The lower surface of the ceramic plate 20 and the upper surface of the cooling plate 30 are joined by TCB to obtain a joined body 94 (FIG. 4B). The TCB is performed, for example, as follows. First, the metal joining material 90 is inserted between the lower surface of the ceramic plate 20 and the upper surface of the cooling plate 30 to form a layered body. In this process, the plug insertion hole 24 of the ceramic plate 20, the circular hole 92 of the metal joining material 90, and the gas hole 34 of the cooling plate 30 are coaxially stacked. The layered body is pressurized and bonded at a temperature (for example, a temperature in the range from the solidus temperature minus 20° C. to the solidus temperature) lower than or equal to the solidus temperature of the metal joining material 90, then is placed at a room temperature. Thus, the metal joining material 90 becomes the metal joining layer 40, the circular hole 92 becomes the circular hole 42, and the joined body 94 is obtained in which the ceramic plate 20 and the cooling plate 30 are joined by the metal joining layer 40. As the metal joining material, an Al—Mg based joining material and an Al—Si—Mg based joining material may be used. For example, when the TCB is performed using an Al—Si—Mg based joining material, the layered body is pressurized in a heated state in a vacuum atmosphere. The metal joining material 90 with a thickness of approximately 100 µm is preferably used.

Subsequently, the insulating pipe 60 is prepared, and after a bonding adhesive is applied to the inner peripheral surface of the circular hole 42 of the metal joining layer 40 and the inner peripheral surface of the gas hole 34 of the cooling plate 30, the insulating pipe 60 is inserted into those holes, and bonded and fixed to the circular hole 42 and the gas hole 34 (FIG. 4C). The bonding adhesive may be a resin (organic) bonding adhesive, or an inorganic bonding adhesive. Subsequently, blasting is performed on the upper surface (the wafer placement surface 21) of the ceramic plate 20 to form the seal band 21a, the small circular projections 21b and the reference surface 21c (see FIG. 3).

Subsequently, the porous plug 50 (porous bulk body) including the male thread portion 52 is prepared (FIG. 4C). As the porous plug 50, a porous material produced in the following manner may be used: a pore-forming agent is added to a ceramic material, which is molded into a cylindrical body having a male thread portion, then the cylindrical body is sintered to burn off the pore-forming agent, thereby producing a porous material.

The male thread portion 52 of the porous plug 50 is screwed into the female thread portion 24b of the plug insertion hole 24 to bring the lower surface of the porous plug 50 into contact with the upper surface (the lower surface of the ceramic plate 20) of the insulating pipe 60 (FIG. 5A). For example, a knob having, at a leading end, a material with a high friction coefficient, such as rubber, is brought into firm contact with the upper surface of the porous plug 50, the knob is rotated while being pushed by a hand, and the porous plug 50 is inserted and screwed into the plug insertion hole 24 through an upper opening thereof. After being screwed thereinto, the knob is removed. When screwing of the porous plug 50 is completed, the upper surface of the porous plug conforms the bottom surface of the cylindrical member 24a of the plug insertion hole 24.

Subsequently, a thermal spray film 96 is formed by spraying ceramic powder to the upper surface of the porous plug 50 (FIG. 5B). Thus, the cylindrical member 24a of the plug insertion hole 24 is filled with the thermal spray film 96. At this point, the male thread portion 52 of the porous plug 50 is screwed into the female thread portion 24b of the plug insertion hole 24, and no gap in an up-down direction has occurred, thus ceramic powder can be sprayed easily. The upper surface of the thermal spray film 96 is raised higher than the upper surface of the ceramic plate 20.

Subsequently, grinding process (machining process) is performed so that the upper surface of the thermal spray film 96 is flush with the reference surface 21c (see FIG. 3) formed on the wafer placement surface 21 of the ceramic plate 20 (FIG. 5C). Consequently, the insulating lid 56 composed of a thermal spray film is formed at the upper portion of the porous plug 50. Subsequently, the plurality of pores 58 are formed in the insulating lid 56 by performing laser processing (FIG. 5D). The member 10 for semiconductor manufacturing apparatus is obtained as described above.

In the member 10 for semiconductor manufacturing apparatus described in detail above, the insulating lid 56, which is a separate body from the ceramic plate 20, is provided with the plurality of pores 58. Therefore, the machinability of the pores is improved, as compared to when the ceramic plate 20 is directly provided with a plurality of pores.

The insulating lid 56 is a thermal spray film. Thus, the insulating lid 56 can be produced relatively easily. Note that the thermal spray film may be porous or may be dense. When a porous film is used, the porosity is preferably 10 to 15%.

Furthermore, the upper surface of the insulating lid 56 is at the same height as the reference surface 21c of the wafer placement surface 21, and the length of the pores 58 in an up-down direction is preferably 0.01 mm or more and 0.5 mm or less. When the length is 0.01 mm or more, favorable machinability is likely to be secured. In addition, when the length is 0.5 mm or less, the height of the space between the rear surface of the wafer W and the upper surface of the porous plug 50 is maintained at a low level, thus it is possible to prevent arc discharge from occurring in the space. Incidentally, when the height of the space is high, arc discharge occurs when electrons generated due to ionization of helium (back side gas) are accelerated to collide with other helium. However, when the height of the space is low, such an arc discharge is prevented.

Furthermore, the diameter of the pores 58 is preferably, 0.01 mm or more and 0.5 mm or less, and the insulating lid 56 is preferably provided with the pores 58 that are five or more in number. In this setting, the back side gas supplied to the porous plug 50 smoothly flows to the rear surface of the wafer W.

The plug insertion hole 24 has the female thread portion 24b on the inner peripheral surface, and the porous plug 50 has the male thread portion 52 to be screwed into the female thread portion 24b on the outer peripheral surface. Therefore, the porous plug 50 can be disposed in the plug insertion hole 24 without using a bonding adhesive. Furthermore, in an area where the male thread portion 52 is screwed into the female thread portion 24b, a vertical gap is unlikely to occur and a creepage distance is increased, as compared to when no thread is provided. Thus, electrical discharge can be sufficiently prevented in the area.

In addition, the upper surface of the porous plug 50 is covered by the insulating lid 56 provided with the pores 58, thus occurrence of particles from the porous plug 50 can be prevented.

Still furthermore, the gas hole 34 is provided with the insulating pipe 60, thus the creepage distance between the wafer W and the cooling plate 30 is increased. Therefore, occurrence of creeping discharge (spark discharge) in the porous plug 50 can be prevented.

Furthermore, the outer shape of the insulating lid 56 and the porous plug 50 is a circle, and the outer diameter of the insulating lid 56 is larger than that of the porous plug 50. Consequently, the adhesion area between the insulating lid 56 and the ceramic plate 20 is increased, thus the adhesiveness between the two becomes favorable.

Needless to say, the present invention is not limited to the embodiment described above, and can be implemented in various modes within the technical scope of the present invention.

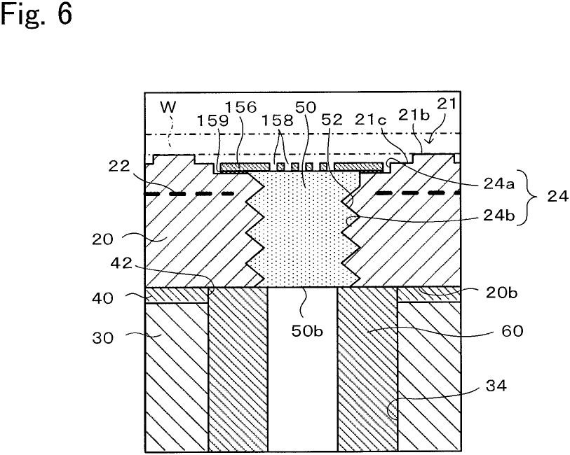

In the embodiment described above, as the insulating lid 56, a thermal spray film is used, but the insulating lid 56 is not particularly limited to a thermal spray film. For example, as illustrated in FIG. 6, an insulating lid 156, which is a dense ceramic bulk body (ceramic sintered body), may be used. In FIG. 6, the same components as in the above embodiment are labeled with the same symbols. The insulating lid 156 has a plurality of pores 158, and is bonded and fixed to the bottom surface of the flat cylindrical member 24a of the plug insertion hole 24 via an adhesive layer 159. The adhesive layer 159 is preferably not in contact with the upper surface of the porous plug 50. The adhesive layer 159 may be a resin (organic) adhesive layer, or an inorganic adhesive layer. An example of a method of producing such an insulating lid 156 will be described below. First, ceramic powder is sintered to produce a dense bulk body. The size of the dense bulk body is such that multiple insulating lids 156 can be taken out therefrom. The dense bulk body is processed so that its thickness reaches a predetermined value of 0.01 mm or more and 0.5 mm or less. After the processing for thickness, laser processing is performed on the dense bulk body to cut out a plurality of insulating lids 156 from the dense bulk body, and a plurality of pores 158 are formed in each insulating lid 156. The size of each insulating lid 156 and the size of each pore 158 are the same as in the above embodiment. Also in FIG. 6, the height of the space between the rear surface of the wafer W and the upper surface of the porous plug 50 is maintained at a low level, thus it is possible to prevent arc discharge from occurring in the space. The adhesive layer 159 is hidden from the wafer side by the insulating lid 156, and even at the time of dry cleaning of a chamber, deterioration of the adhesive layer 159 is prevented. Alternatively, the insulating lid 156 may be produced by laser sintering.

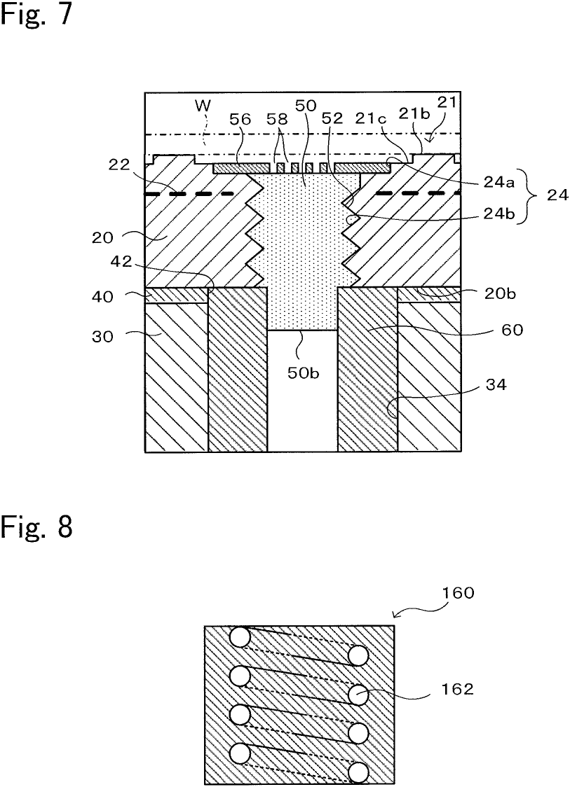

In the above embodiment, the lower surface 50b of the porous plug 50 conforms the lower surface 20b of the ceramic plate 20; however, the configuration is not limited thereto. For example, as illustrated in FIG. 7, the lower surface 50b of the porous plug 50 may be located inside the insulating pipe 60. In FIG. 7, the same components as in the above embodiment are labeled with the same symbols. In FIG. 7, the lower surface 50b of the porous plug 50 is located inside the communication hole (the circular hole 42 and the gas hole 34) of the conductive substrate (the metal joining layer 40 and the cooling plate 30). In this manner, it is possible to prevent arc discharge from occurring between the lower surface 50b of the porous plug 50 and the conductive substrate. This is because arc discharge occurs due to a potential difference between the lower surface 50b of the porous plug 50 and the conductive substrate when the lower surface 50b of the porous plug 50 is located above the upper surface (the upper surface of the metal joining layer 40) of the conductive substrate, but with the configuration as in FIG. 7, such electric discharge does not occur.

In the above embodiment, the insulating pipe 60 is used; however, instead of the insulating pipe 60, an insulating plug 160 in which a gas passage 162 illustrated in FIG. 8 is embedded may be used. The insulating pipe 160 is such that a spiral gas passage 162 is provided inside a cylindrical body composed of dense ceramic. The upper end of the gas passage 162 is opened in the upper surface of the cylindrical body, and the lower end of the gas passage 162 is opened in the lower surface of the cylindrical body. When the insulating plug 160 is used, the creepage distance between the wafer W and the cooling plate 30 is longer than when the insulating pipe 60 is used, thus occurrence of spark discharge in the porous plug 50 can be further prevented.

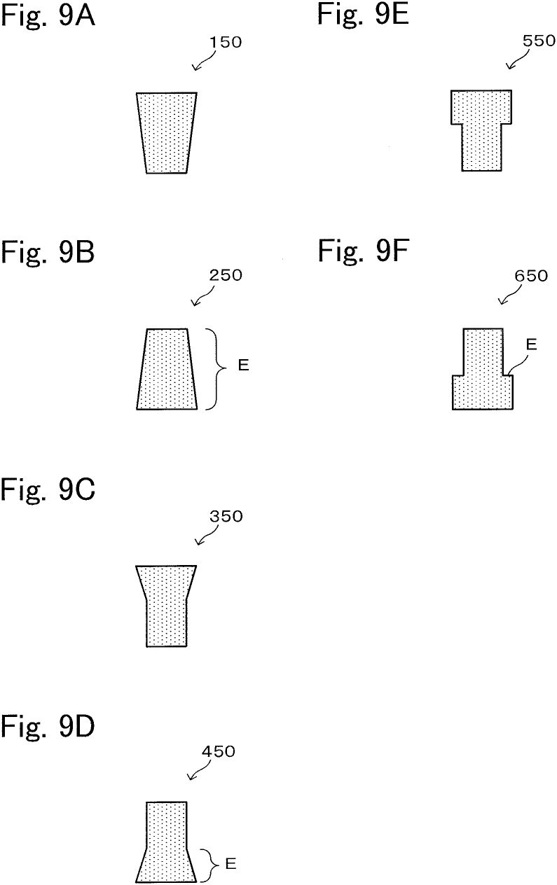

Instead of the porous plug 50 of the above embodiment, porous plugs 150 to 650 illustrated in FIGS. 9 may be used. When these porous plugs 150 to 650 are used, respective plug insertion holes 24 provided in the ceramic plate 20 are changed to corresponding shapes. The porous plug 150 of FIG. 9A has an inverted circular truncated cone shape with an upper base larger than a lower base. The porous plug 250 of FIG. 9B has a circular truncated cone shape with a lower base larger than an upper base. The porous plug 350 of FIG. 9C has a shape with a cylinder connected to the lower surface of an inverted circular truncated cone. The porous plug 450 of FIG. 9D has a shape with a cylinder connected to the upper surface of a circular truncated cone. The porous plug 550 of FIG. 9E has a shape with a small-diameter cylinder connected to the lower surface of a large-diameter cylinder. The porous plug 650 of FIG. 9F has a shape with a large-diameter cylinder connected to the lower surface of a small-diameter cylinder. Of these, the porous plugs 250, 450, 650 each have an enlarged-diameter section E that has a larger diameter at a lower position. Thus, even when the pressure of a gas flowing upward from below the porous plugs 250, 450, 650 is applied thereto, the enlarged-diameter section E is brought into firm contact with the inner peripheral surface of the plug insertion hole, thus the porous plugs 250, 450, 650 can be prevented from floating. The outer peripheral surfaces of these porous plugs 150 to 650 may be each provided with a male thread portion to be screwed into a female thread portion of a plug insertion hole as in the above embodiment.

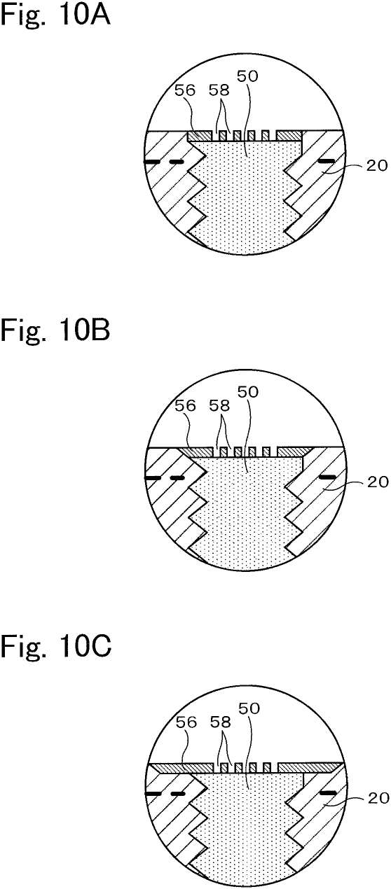

In the above embodiment, the insulating lid 56 has a circular plate shape with an upper base and a lower base in the same size which is larger than the upper surface of the porous plug 50; however, the shape of the insulating lid 56 may be as illustrated in FIGS. 10A to 10C. The insulating lid 56 of FIG. 10A has a circular plate shape with an upper base and a lower base in the same size which is the same as the upper surface of the porous plug 50. However, as compared to FIG. 10A, the adhesiveness between the insulating lid 56 and the porous plug 50 as well as the adhesiveness between the insulating lid 56 and the ceramic plate 20 are more favorable than in the above embodiment. The insulating lid 56 of FIG. 10B has an inverted circular truncated cone shape with an upper base larger than a lower base which is the same in size as the upper surface of the porous plug 50. In this case, as compared to FIG. 10A, the area of the outer peripheral surface of the insulating lid 56 is increased, thus the adhesiveness between the outer peripheral surface of the insulating lid 56 and the ceramic plate 20 is more favorable. The insulating lid 56 of FIG. 10C has an inverted circular truncated cone shape with an upper base larger than a lower base which is larger than the upper surface of the porous plug 50. In this case, as compared to the above embodiment, the adhesiveness between the insulating lid 56 and the ceramic plate 20 is more favorable. Particularly, when the insulating lid 56 is formed by thermal spray, the shape of the insulating lid 56 is more preferable in FIG. 10B than in FIG. 10A, more preferable in the above embodiment than in FIG. 10B, and more preferable in FIG. 10C than in the above embodiment.

In the above embodiment, the insulating lid 56 has a circular plate shape with an upper base and a lower base in the same size; however, the insulating lid 56 may be an inverted circular truncated cone with an upper base larger than a lower base. In this case, the cylindrical member 24a of the plug insertion hole 24 is a space in an inverted circular truncated cone shape. In this manner, when the insulating lid 56 is formed with thermal spray films, the cylindrical member 24a of the plug insertion hole 24 is likely to be filled with thermal spray films. In addition, the contact area between the insulating lid 56 and the cylindrical member 24a of the plug insertion hole 24 is increased, thus the adhesiveness between the insulating lid 56 and the plug insertion hole 24 is improved.

In the above embodiment, the male thread portion 52 is formed on the outer peripheral surface of the porous plug 50, the female thread portion 24b is formed on the inner peripheral surface of the plug insertion hole 24, and the male thread portion 52 is screwed into the female thread portion 24b; however, the configuration is not limited thereto. For example, the male thread portion 52 may not be formed on the outer peripheral surface of the porous plug 50, and the female thread portion 24b may not be formed on the inner peripheral surface of the plug insertion hole 24. In this case, the outer peripheral surface of the porous plug 50 and the inner peripheral surface of the plug insertion hole 24 may be bonded by a bonding adhesive (an organic bonding adhesive or an inorganic bonding adhesive may be used). However, it is difficult to fill the space between the outer peripheral surface of the porous plug 50 and the inner peripheral surface of the plug insertion hole 24 with a bonding adhesive without creating a gap. When a gap is created, electric discharge may occur in the gap. Thus, the structure (structure in which the male thread portion 52 is screwed into the female thread portion 24b) of the above embodiment is more preferable.

In the above embodiment, the insulating pipe 60 is provided; however, the insulating pipe 60 may be omitted. Alternatively, instead of providing the cooling plate 30 with the gas hole 34, a gas channel structure may be provided. As the gas channel structure, a structure may be adopted which includes: a ring section provided inside the cooling plate 30 and concentric therewith in a plan view; an introduction section for introducing a gas from the rear surface of the cooling plate 30 to the ring section; and a distribution section (corresponding to the above-described gas hole 34) that distributes a gas from the ring section to each porous plug 50. The number of introduction sections may be smaller than the number of distribution sections, and may be one, for example.

In the above embodiment, an electrostatic electrode is illustrated as the electrode 22 to be embedded in the ceramic plate 20; however, the configuration is not limited thereto. For example, in replacement of or in addition to the electrode 22, a heater electrode (resistance heating element) may be embedded in the ceramic plate 20, or an RF electrode may be embedded therein.

In the above embodiment, the ceramic plate 20 and the cooling plate 30 are joined by the metal joining layer 40; however, a resin adhesive layer may be used in replacement of the metal joining layer 40. In this case, the cooling plate 30 corresponds to the conductive substrate of the present invention.

The present application claims priority from Japanese Patent Application No. 2022-007943, filed on Jan. 21, 2022, the entire contents of which are incorporated herein by reference.

What is claimed is:

1. A member for semiconductor manufacturing apparatus, comprising:
a ceramic plate that has an upper surface including a wafer placement surface;
a porous plug that is disposed in a plug insertion hole penetrating the ceramic plate in an up-down direction, and allows gas to flow;
an insulating lid that is provided in contact with an upper surface of the porous plug, and exposed to the wafer placement surface; and
a plurality of pores penetrating the insulating lid in an up-down direction.

2. The member for semiconductor manufacturing apparatus according to claim 1,
wherein the insulating lid is a thermal spray film or a ceramic bulk body.

3. The member for semiconductor manufacturing apparatus according to claim 1,
wherein the wafer.placement surface has a large number of small projections that support a wafer,
an upper surface of the insulating lid is at a same height as a reference surface of the wafer placement surface, the reference surface being not provided with the small projections, and
the pores have a length of 0.01 mm or more and 0.5 mm or less in an up-down direction.

4. The member for semiconductor manufacturing apparatus according to claim 3,
wherein the insulating lid is a ceramic bulk body, and has a rear surface bonded to the ceramic plate via an adhesive layer.

5. The member for semiconductor manufacturing apparatus according to claim 1,
wherein the pores have a diameter of 0.01 mm or more and 0.5 mm or less, and the insulating lid is provided with the pores that are five or more in number.

6. The member for semiconductor manufacturing apparatus according to claim 1,
wherein the plug insertion hole has a female thread portion on an inner peripheral surface, and the porous plug has a male thread portion to be screwed into the female thread portion, on an outer peripheral surface.

7. The member for semiconductor manufacturing apparatus according to claim 1,
wherein the porous plug has an enlarged-diameter section that has a larger diameter at a lower position.

8. The member for semiconductor manufacturing apparatus according to claim 1,
wherein the insulating lid and the porous plug have circular outlines, and an outer diameter of the insulating lid is larger than an outer diameter of the porous plug.
